(19) United States
(12) Patent Application Publication
(10) Pub. No.: US 2025/0014874 A1
(43) Pub. Date: Jan. 9, 2025

(54) ELECTROSTATIC CHUCK AND PLASMA PROCESSING APPARATUS

(71) Applicant: Tokyo Electron Limited, Tokyo (JP)

(72) Inventor: Takahiko SATO, Miyagi (JP)

(73) Assignee: Tokyo Electron Limited, Tokyo (JP)

(21) Appl. No.: 18/892,781

(22) Filed: Sep. 23, 2024

Related U.S. Application Data
(63) Continuation of application No. PCT/JP2023/009616, filed on Mar. 13, 2023.
(60) Provisional application No. 63/322,920, filed on Mar. 23, 2022.

(51) Int. Cl. H01J 37/32; H01L 21/683

(52) U.S. Cl. CPC H01J 37/32715; H01L 21/6833; H01J 2237/2007

(57) ABSTRACT

An electrostatic chuck for supporting a substrate includes a dielectric member having a substrate support surface, a groove formed on an upper surface of the dielectric member, and a plurality of electrode layer segments to which a high voltage is applied. The plurality of electrode layer segments are located in the dielectric member. At least one electrode layer segment of the plurality of electrode layer segments is located under a portion of the upper surface of the dielectric member where the groove is not formed. None of the plurality of electrode layer segments is located at a position under the groove and higher than the at least one electrode layer segment.

### CROSS-REFERENCE TO RELATED APPLICATIONS

This application is a bypass continuation application of International Application No. PCT/JP2023/009616 having an international filing date of Mar. 13, 2023, and designating the United States, the International Application being based upon and claiming the benefit of priority from the U.S. Patent Application No. 63/322,920 filed on Mar. 23, 2022, the entire contents of each are incorporated herein by reference.

### TECHNICAL FIELD

The disclosure relates to an electrostatic chuck (ESC) and a plasma processing apparatus.

### BACKGROUND

Japanese Laid-open Patent Publication No. 2021-163831 describes a plasma processing apparatus including an ESC. The ESC includes an electrode to which a voltage is applied to clamp and hold a substrate. The ESC includes multiple protrusions on its upper surface.

### SUMMARY

One or more aspects of the disclosure are directed to a technique for allowing maintenance and reuse of an ESC with reduced abnormal discharge between the ESC and a substrate.

According to one aspect of the disclosure, an electrostatic chuck includes a dielectric member having a substrate support surface, a groove formed on an upper surface of the dielectric member, and a plurality of electrode layer segments to which a high voltage is applied. The plurality of electrode layer segments are located in the dielectric member. At least one electrode layer segment of the plurality of electrode layer segments is located under a portion of the upper surface of the dielectric member where the groove is not formed. None of the plurality of electrode layer segments is located at a position under the groove and higher than the at least one electrode layer segment. The high voltage according to the disclosure includes, for example, a high voltage applied to a clamping electrode for clamping the substrate and a high voltage applied to a bias electrode for drawing ion components in plasma to the substrate.

### BRIEF DESCRIPTION OF THE DRAWINGS

FIG. 1 is a diagram of a plasma processing system with an example structure.

FIG. 2 is a block diagram of a computer-based system that functions as a controller for controlling processes performed in various embodiments of the disclosure.

FIG. 3 is a diagram of a capacitively coupled plasma processing apparatus with an example structure.

FIG. 4 is a schematic plan view of an ESC according to a first embodiment.

FIG. 5 is a schematic sectional view of the ESC according to the first embodiment.

FIG. 6 is a sectional perspective view of the ESC according to the first embodiment, showing a portion around a heat transfer gas supply hole.

FIG. 7 is a sectional perspective view of the ESC according to the first embodiment, showing a portion around a lifter pin through-hole.

FIG. 8 is a diagram of a clamping electrode layer, protrusions, and a groove, showing their dimensions and positional relationship.

FIG. 9 is a schematic sectional view of an ESC according to a second embodiment.

FIG. 10 is a schematic plan view of an ESC according to a third embodiment.

FIG. 11 is a schematic sectional view of an ESC according to a fourth embodiment.

FIG. 12 is a schematic sectional view of an ESC according to a fifth embodiment.

FIG. 13 is a schematic sectional view of an ESC according to a sixth embodiment.

FIG. 14 is a schematic sectional view of an ESC according to another embodiment.

FIGS. 15A to 15C are diagrams of a known ESC undergoing plasma processing and formation of new protrusions.

### DETAILED DESCRIPTION

In the process of manufacturing semiconductor devices, for example, a plasma processing apparatus is used to perform plasma processing on a semiconductor substrate (hereafter referred to as a substrate). The plasma processing apparatus excites a process gas in a chamber to generate plasma, which is then used to process the substrate supported on an electrostatic chuck (ESC).

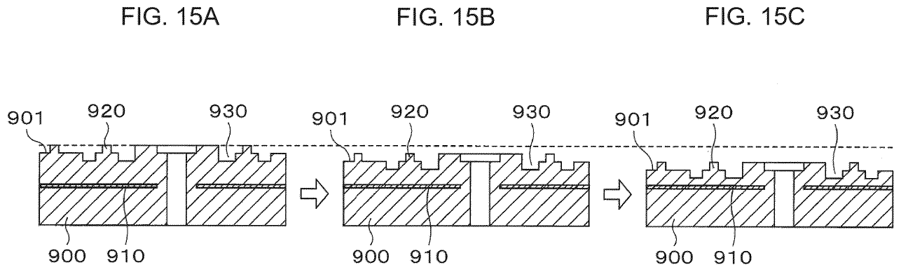

For example, Japanese Laid-open Patent Publication No. 2021-163831 describes an ESC 900 shown in FIG. 15A. The ESC 900 includes an electrode 910 inside the ESC 900 to clamp and support a substrate. The ESC 900 has multiple protrusions 920 on an upper surface 901 to come in contact with and support the substrate. The ESC 900 may also have multiple grooves 930 recessed from the upper surface 901.

When plasma processing is performed on the substrate, the upper surface 901 of the ESC 900 wears down and its level is lowered as shown in FIG. 15B. The upper surface 901 is degraded by exposure to plasma in the plasma processing, and is thus machined to form new multiple protrusions 920 (formation of new protrusions) as shown in FIG. 15C. The ESC 900 is thus maintained and reused.

However, after the plasma processing is performed and the new protrusions are formed, the distance between the bottom surfaces of the grooves 930 and the electrode 910 is shorter. More specifically, the portion of the dielectric member in the ESC 900 between the bottom surfaces of the grooves 930 and the electrode 910 is thinner than the portion of the dielectric member in the ESC 900 between the upper surface 901 and the electrode 910. This may decrease the dielectric strength of the grooves 930 and decrease the withstand voltage margin between the upper surface 901 of the ESC 900 and the substrate, possibly causing abnormal discharge between the upper surface 901 and the substrate.

To avoid such abnormal discharge (a decrease in the withstand voltage margin), for example, the electrode 910 may be located farther from the upper surface 901 of the ESC 900. However, this may decrease the clamping force and cause insufficient clamping of the substrate. In another example, the ESC 900 may be machined more accurately to reduce variations in the thickness of the dielectric member. However, known ESCs are machined using nearly criteria of stable machining, and seeking more accurate machining is less cost-effective. The structure of the ESC is to be improved.

Under such circumstances, one or more aspects of the disclosure are directed to a technique for allowing maintenance and reuse of an ESC with reduced abnormal discharge between the ESC and a substrate. A plasma processing apparatus and an ESC according to the present embodiment will now be described with reference to the drawings. Like reference numerals denote components having substantially the same functions herein and in the drawings. Such components will not be described repeatedly.

### Plasma Processing System

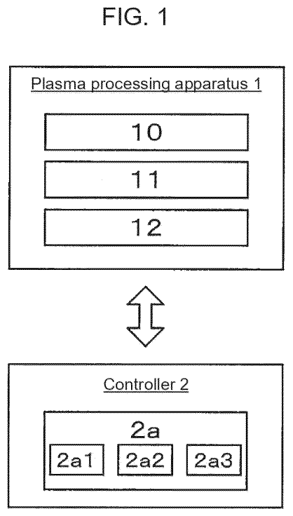

A plasma processing system according to one embodiment will be described first with reference to FIG. 1. FIG. 1 is a diagram of a plasma processing system with an example structure.

In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for receiving at least one process gas to be supplied into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

The control methods and the systems described herein may be implemented using computer programming or engineering techniques including computer software, firmware, hardware or any combination or subset of these. The technical effects according to one or more embodiments of the disclosure may include at least processing of a substrate in the plasma processing apparatus 1 including the ESC.

### Computer

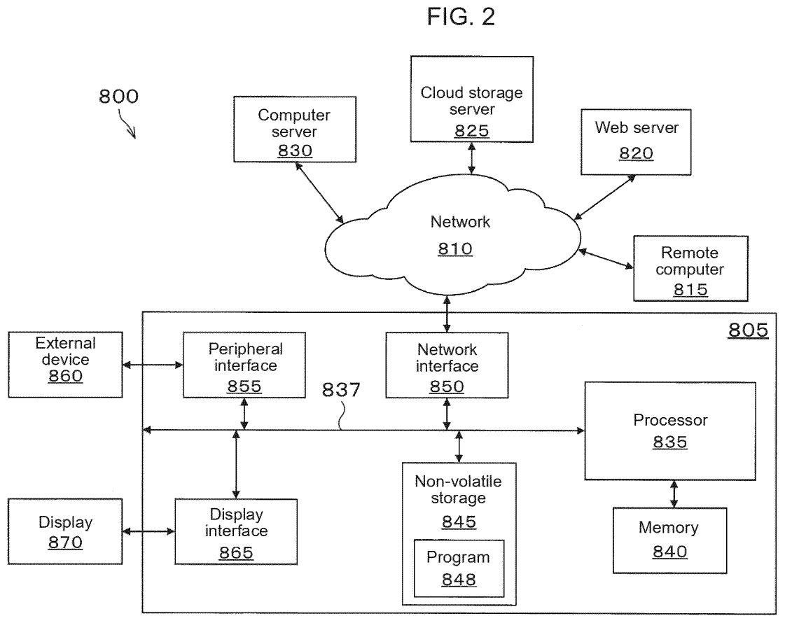

FIG. 2 is a block diagram of a computer (as a type of circuit) that may implement the various embodiments described herein. The computer in FIG. 2 corresponds to the above computer 2a. The control aspects in one or more embodiments of the disclosure may be embodied as at least one of a system, a method, or a computer program product. The computer program product may include a computer-readable storage medium on which computer-readable program instructions are recorded to cause one or more processors to implement aspects of the embodiments.

The computer-readable storage medium may be a tangible device that can store instructions for use by an instruction execution device (processor). The computer-readable storage medium may be, for example, but not limited to, an electronic storage device, a magnetic storage device, an optical storage device, an electromagnetic storage device, a semiconductor storage device, or any appropriate combination of these devices. A non-exhaustive list of more specific examples of the computer-readable storage medium (and appropriate combinations) includes a flexible disk, an HDD, an SSD, a RAM, a ROM, a programmable ROM (an erasable programmable ROM or EPROM, or a flash memory), a static RAM (SRAM), a compact disc (CD, or a CD-ROM), a digital versatile disk (DVD), and a memory card or stick. The computer-readable storage medium as used in one or more embodiments of the disclosure is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

The computer-readable program instructions described in one or more embodiments of the disclosure can be downloaded from a computer-readable storage medium to an appropriate computing or processing device or to an external computer or an external storage device through at least one of a global network (specifically, the Internet), a LAN, a wide area network (WAN), or a wireless network. The network may include copper transmission wires, optical communication fibers, wireless transmission, routers, firewalls, switches, gateway computers, or edge servers. A network adapter card or a network interface in each computing or processing device may receive computer-readable program instructions from the network and forward the computer-readable program instructions for storage in a computer-readable storage medium within the computing or processing device.

The computer-readable program instructions for performing operations in one or more embodiments of the disclosure may include machine language instructions, a microcode, or both. Such instructions may be compiled or interpreted from a source code written in any combination of one or more programming languages including an assembly language, Basic, Fortran, Java, Python, R, C, C++, C# and similar programming languages. The computer-readable program instructions may be executed entirely on a personal computer (PC), a notebook computer, a tablet, or a smartphone of a user, on a remote computer or a computer server, or on any combination of these computing devices. The remote computer or computer server may be connected to the user's device or devices through a computer network, including a LAN, a WAN, or a global network (specifically, the Internet). In some embodiments, electronic circuitry including, for example, programmable logic circuitry, field-programmable gate arrays (FPGAs), or programmable logic arrays (PLAs) may execute the computer-readable program instructions by using information from the computer-readable program instructions to configure or customize the electronic circuitry and perform aspects of the disclosure.

Aspects of the disclosure are described herein with reference to the apparatuses (systems) and the computer program products according to embodiments of the disclosure. Those skilled in the art will understand that each block of the block diagrams, and combinations of block diagrams can be implemented by computer-readable program instructions.

The computer-readable program instructions that may implement the systems and methods described in one or more embodiments of the disclosure may be provided to one or more processors (or one or more cores within the processors, or both the processors and the cores) of a general-purpose computer, a special-purpose computer, or another programmable apparatus. These computer-readable program instructions, which are executed with the processors of the computer or the other programmable apparatus, create a system for implementing the functions specified in the block diagrams in one or more embodiments of the disclosure. The computer-readable program instructions may also be stored in a computer-readable storage medium that can direct at least one of a computer, a programmable apparatus, or another device to function in a particular manner. The computer-readable storage medium having stored instructions is a product including instructions that implement aspects of the functions specified in the block diagrams in one or more embodiments of the disclosure.

The computer-readable program instructions may also be loaded onto a computer, another programmable apparatus, or another device to cause, when executed on the computer, the apparatus, or the device, a series of operational steps to be performed to produce a computer-implementable process to implement the functions specified in the block diagrams in one or more embodiments of the disclosure.

FIG. 2 is a functional block diagram of a networked system 800 of one or more networked computers and servers. In one embodiment, the hardware and software environment shown in FIG. 2 may provide an exemplary platform for implementing the software, the methods, or both according to one or more embodiments of the disclosure.

As shown in FIG. 2, the networked system 800 may include, but is not limited to, a computer 805, a network 810, a remote computer 815, a web server 820, a cloud storage server 825, and a computer server 830. In some embodiments, multiple instances of one or more of the functional blocks shown in FIG. 2 may be used.

FIG. 2 shows additional details of the computer 805. The functional blocks shown in the computer 805 are provided merely to establish exemplary functions and are not intended to be exhaustive. Although details are not provided for the remote computer 815, the web server 820, the cloud storage server 825, or the computer server 830, these other computers and devices may include functions similar to the illustrated functions of the computer 805.

The computer 805 may be a PC, a desktop computer, a laptop computer, a tablet computer, a netbook computer, a personal digital assistant (PDA), a smartphone, or any other programmable electronic device that can communicate with other devices on the network 810.

The computer 805 may include a processor 835, a bus 837, a memory 840, a non-volatile storage 845, a network interface 850, a peripheral interface 855, and a display interface 865. In some embodiments, each of these functions may be implemented as an individual electronic subsystem (an integrated circuit chip or a combination of chips and associated devices). In other embodiments, a combination of the functions may be implemented on a single chip (also referred to as a system on a chip, or an SoC).

The processor 835 may be one or more single-or multi-chip microprocessors.

The bus 837 may be a proprietary or standard high-speed parallel or serial peripheral interconnect bus, such as Industry Standard Architecture (ISA), Peripheral Component Interconnect (PCI), PCI Express (PCle), or Accelerated Graphics Port (AGP).

The memory 840 and the non-volatile storage 845 may be computer-readable storage media. The memory 840 may include any suitable volatile storage devices such as a dynamic RAM (DRAM) and a static RAM (SRAM). The non-volatile storage 845 may include at least one of a flexible disk, an HDD, an SSD, a ROM, a programmable ROM (an EPROM or a flash memory), a CD (or a CD-ROM), a DVD, or a memory card or stick.

A program 848 may be a collection of machine-readable instructions, data, or both that is stored in the non-volatile storage 845 and is used to create, manage, and control specific software functions described in detail elsewhere herein and illustrated. In some embodiments, the memory 840 may be much faster than the non-volatile storage 845. In such embodiments, the program 848 may be transferred from the non-volatile storage 845 to the memory 840 before being executed by the processor 835.

The computer 805 may communicate and interact with other computers through the network 810 using the network interface 850. The network 810 may be, for example, a LAN, a WAN such as the Internet, or a combination of these, and may include wired, wireless, or fiber optic connections. In general, the network 810 may be any combination of connections and protocols that support communications between two or more computers and associated devices.

The peripheral interface 855 may allow input and output of data to and from other devices that may be connected locally to the computer 805. For example, the peripheral interface 855 may provide a connection to external devices 860. The external devices 860 may include at least one of a keyboard, a mouse, a keypad, a touchscreen, or other suitable input devices. The external devices 860 may also include portable computer-readable storage media, such as thumb drives, portable optical or magnetic disks, and memory cards. The software and data used to practice embodiments of the disclosure (e.g., the program 848) may be stored in such portable computer-readable storage media. In such embodiments, the software may be loaded onto the non-volatile storage 845, or may be directly loaded onto the memory 840 through the peripheral interface 855. The peripheral interface 855 may use an industry standard connection, such as Recommended Standard 232 (RS-232) or a universal serial bus (USB) to connect to the external devices 860.

The display interface 865 may connect the computer 805 to a display 870. In some embodiments, the display 870 may be used to present a command line or a graphical user interface to a user of the computer 805. The display interface 865 may use one or more proprietary or industry standard connections, such as Video Graphics Array (VGA), Digital Visual Interface (DVI), DisplayPort (DP), and High-Definition Multimedia Interface (HDMI, registered trademark), to connect to the display 870.

As described above, the network interface 850 provides communications with other computing and storage systems or devices external to the computer 805. The software programs and data described herein may be downloaded from, for example, the remote computer 815, the web server 820, the cloud storage server 825, and the computer server 830 to the non-volatile storage 845 through the network interface 850 and the network 810. Further, the systems and methods described in one or more embodiments of the disclosure may be implemented by one or more computers connected to the computer 805 through the network interface 850 and the network 810. In some embodiments, for example, the systems and methods described in one or more embodiments of the disclosure may be implemented by the remote computer 815, the computer server 830, or a combination of interconnected computers on the network 810.

At least one of data, datasets, or databases used in the systems and methods described in one or more embodiments of the disclosure may be stored or downloaded from the remote computer 815, the web server 820, the cloud storage server 825, and the computer server 830.

### Plasma Processing Apparatus

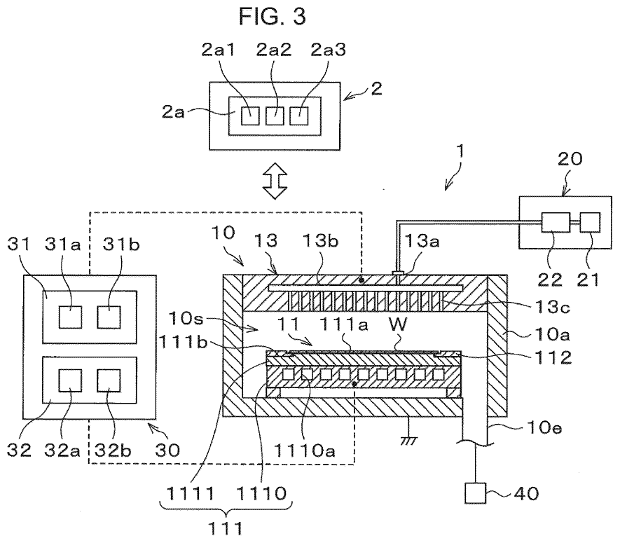

An example structure of a capacitively coupled plasma processing apparatus as an example of the plasma processing apparatus 1 will now be described. FIG. 3 is a diagram of a capacitively coupled plasma processing apparatus 1 with an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas inlet unit as an example of a substrate support unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. The substrate W is, for example, a wafer. The annular portion 111b of the body 111 surrounds the central portion 111a of the body 111 in a plan view. The substrate W is placed on the central portion 111a of the body 111. The ring assembly 112 is placed on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an ESC 1111. The base 1110 is substantially disk-shaped and includes a conductive member formed from, for example, aluminum. The conductive member in the base 1110 may serve as a lower electrode. The ESC 1111 is located on the base 1110. The ESC 1111 includes the central portion 111a. In one embodiment, the ESC 1111 also includes the annular portion 111b. The structure of the ESC 1111 will be described later.

The annular portion 111b may be included in a separate member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF electrode coupled to an RF power supply 31 (described later), at least one DC electrode coupled to a DC power supply 32 (described later), or both these electrodes may be located inside the ESC 1111. In this case, the RF electrode(s), the DC electrode(s), or both these electrodes serve as lower electrodes. When a bias RF signal (described later), a DC signal (described later), or both these signals are provided to the RF electrode(s), the DC electrode(s), or both these electrodes, the electrode(s) is also referred to as a bias electrode(s). The RF electrode(s), the DC electrode(s), or both these electrodes as well as the conductive member in the base 1110 may serve as multiple lower electrodes. An electrode included in the ESC 1111 may also serve as a lower electrode. Thus, the substrate support 11 includes at least one lower electrode.

The ring assembly 112 includes one or more annular members. In one embodiment, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate W to a target temperature. The temperature control module may include a heater, a heat transfer medium, a channel 1110a, or a combination of these. The channel 1110a allows a heat transfer fluid such as brine or gas to flow. In one embodiment, the channel 1110a is defined in the base 1110, and one or more heaters are located in the ESC 1111. The substrate support 11 may include a heat transfer gas supply to supply a heat transfer gas into a space between the back surface of the substrate W and the central portion 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. The gas inlet unit may include, in addition to the shower head 13, one or more side gas injectors (SGIs) installed in one or more openings in the side wall 10a.

The gas supply 20 may include at least one gas source 21 and at least one flow controller 22. In one embodiment, the gas supply 20 allows supply of at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated source RF signal or the generated multiple source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHZ. In one embodiment, the second RF generator 31b may generate multiple bias RF signals with different frequencies. The generated bias RF signal or the generated multiple bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle.

The power supply 30 may include the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

### ESC

The structure of the ESC 1111 described above will now be described in different exemplary embodiments.

### First Embodiment

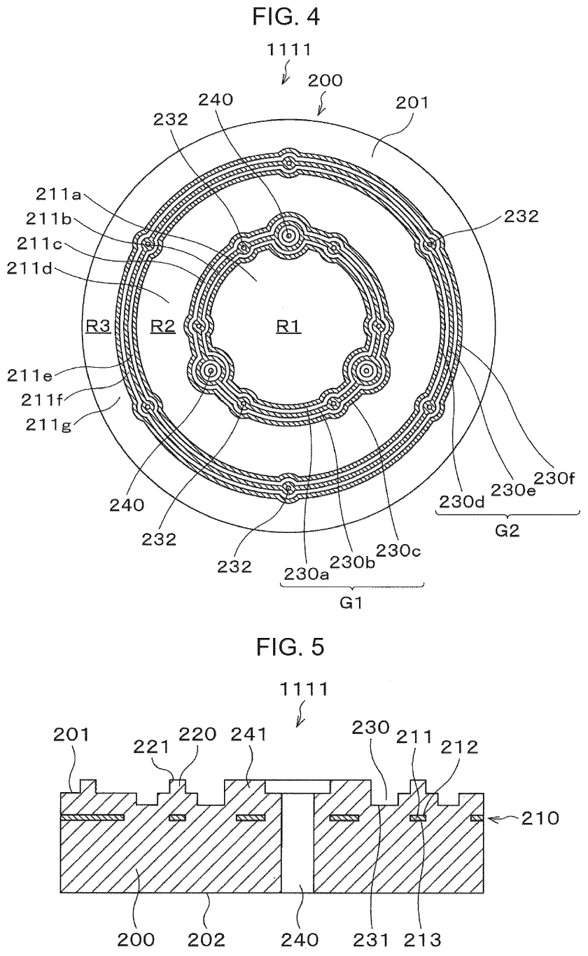

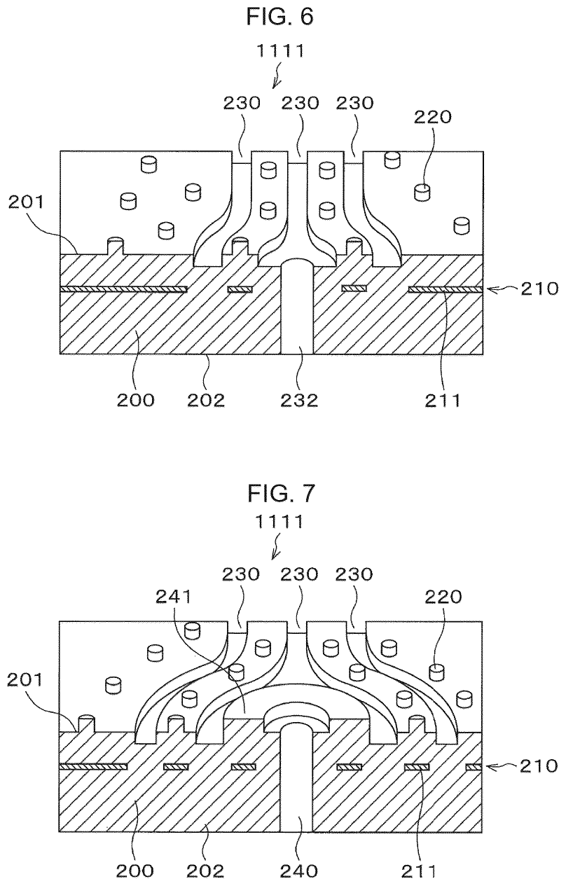

FIG. 4 is a schematic plan view of the ESC 1111 according to a first embodiment. FIG. 5 is a schematic sectional view of the ESC 1111 according to the first embodiment. FIG. 6 is a sectional perspective view of the ESC 1111 according to the first embodiment, showing a portion around a heat transfer gas supply hole 232. FIG. 7 is a sectional perspective view of the ESC 1111 according to the first embodiment, showing a portion around a lifter pin through-hole 240.

As shown in FIGS. 4 to 7, the ESC 1111 includes a dielectric member 200. The dielectric member 200 includes a dielectric formed from a ceramic material such as alumina (Al₂O₃). The dielectric member 200 is substantially disk-shaped. The dielectric member 200 includes the central portion 111a described above, i.e., a substrate support surface for supporting the substrate W. The dielectric member 200 includes the annular portion 111b, i.e., a ring support surface for supporting the ring assembly 112.

The dielectric member 200 includes a clamping electrode layer 210. The clamping electrode layer 210 is coupled to, for example, the first DC generator 32a that applies a high DC voltage to the clamping electrode layer 210. In response to the DC voltage applied to the clamping electrode layer 210, the ESC 1111 generates a Coulomb force to clamp the substrate W. The clamping electrode layer 210 includes multiple clamping electrode layer segments 211. The multiple clamping electrode layer segments 211 are arranged in the manner described later. The dielectric member 200 may include a heater (not shown).

The dielectric member 200 includes multiple protrusions 220 on an upper surface 201 of the dielectric member 200. The protrusions 220 are columnar and protrude from the upper surface 201. Each protrusion 220 has an upper surface 221 that is a substrate contact portion. The upper surfaces 221 of the multiple protrusions 220 define the substrate support surface for supporting the substrate W. In FIG. 4, the multiple protrusions 220 are not shown.

The dielectric member 200 has at least one groove 230 on the upper surface 201. The groove 230 is recessed from the upper surface 201 and looped, or specifically, annular in the present embodiment. The groove 230 is substantially rectangular in a sectional view. The dielectric member 200 may include multiple grooves 230 that may be arranged in the manner described later. The grooves 230 may have any shape other than annular shapes.

Each groove 230 has a bottom surface 231 in which the heat transfer gas supply hole 232 is located for supplying the heat transfer gas. The heat transfer gas supply hole 232 extends through the dielectric member 200 from the bottom surface 231 of the groove 230 to a lower surface 202 of the dielectric member 200. Multiple heat transfer gas supply holes 232 may be located in each of groove sets G1 and G2 (described later). For example, six heat transfer gas supply holes 232 may be located in a groove 230b in a first groove set G1, and six heat transfer gas supply holes 232 may be located in a groove 230e in a second groove set G2. The heat transfer gas (backside gas) may be, for example, a helium gas.

The heat transfer gas supplied through the heat transfer gas supply holes 232 flows through the grooves 230 and diffuses in the circumferential direction of the dielectric member 200. The pressure of the heat transfer gas supplied to the grooves 230 is controlled to produce a pressure difference in the radial direction in the space between the back surface of the substrate W and the upper surface 201 of the dielectric member 200. The pressure difference can be used to control the temperature distribution across the substrate W.

The dielectric member 200 has lifter pin through-holes 240 extending from the upper surface 201 to the lower surface 202 of the dielectric member 200. For example, the dielectric member 200 has three lifter pin through-holes 240. The lifter pin through-holes 240 receive lifter pins (not shown, also referred to as pusher pins) for raising and lowering the substrate W relative to the substrate support 11.

The lifter pin through-holes 240 may be evacuated to avoid abnormal discharge. In this case, each lifter pin through-hole 240 is surrounded by a seal band 241 that comes in contact with the substrate W to support the substrate W. The seal band 241 in contact with the substrate W can reduce the pressure inside the lifter pin through-hole 240.

In one embodiment, the lifter pin through-holes 240 are concentric with the grooves 230. The corresponding groove 230 surrounds the lifter pin through-holes 240 and the seal bands 241. More specifically, the corresponding groove 230 branches along the outer sides of the lifter pin through-holes 240 and the seal bands 241.

The arrangement of the multiple clamping electrode layer segments 211 of the clamping electrode layer 210 described above and the multiple grooves 230 will now be described. In one embodiment, the dielectric member 200 has multiple (e.g., six) grooves 230a to 230f on the upper surface 201. The grooves 230a to 230f are arranged in this order from inward to outward in the radial direction. The grooves 230a to 230f are collectively referred to as the grooves 230. The six grooves 230a to 230f have the centers aligned with the center of the upper surface 201 in a plan view. In other words, the six grooves 230a to 230f are concentric.

In one embodiment, the six grooves 230a to 230f are included in, for example, the two groove sets G1 and G2. The two groove sets G1 and G2 are arranged in this order from inward to outward in the radial direction. The first groove set G1 includes the three grooves 230a to 230c. The second groove set G2 includes the three grooves 230d to 230f. The two groove sets G1 and G2 divide the upper surface 201 into three areas R1 to R3. The first area R1 is a circular central area radially inward from the first groove set G1. The second area R2 is a looped middle area between the first groove set G1 and the second groove set G2. The third area R3 is a looped edge area radially outward from the second groove set G2. The dielectric member 200 may include three or more groove sets, instead of including the two groove sets in the present embodiment.

The clamping electrode layer 210 includes the multiple clamping electrode layer segments 211 into which the clamping electrode layer 210 is divided in the radial direction, in the circumferential direction, or in both these directions. In one embodiment, the clamping electrode layer 210 includes multiple clamping electrode layer segments 211a to 211g. The clamping electrode layer segments 211a to 211g are collectively referred to as the clamping electrode layer segments 211. The clamping electrode layer segment 211a is circular. The other clamping electrode layer segments 211b to 211g are annular.

The clamping electrode layer segments 211 are located under a portion of the upper surface 201 of the dielectric member 200 where the grooves 230 are not formed, and are not located under the bottom surfaces 231 of the grooves 230. More specifically, the clamping electrode layer segment 211a is located under the first area R1. The clamping electrode layer segment 211b is located under the portion between the grooves 230a and 230b. The clamping electrode layer segment 211c is located under the portion between the grooves 230b and 230c. The clamping electrode layer segment 211d is located under the second area R2. The clamping electrode layer segment 211e is located under the portion between the grooves 230d and 230e. The clamping electrode layer segment 211f is located under the portion between the grooves 230e and 230f. The clamping electrode layer segment 211g is located under the third area R3.

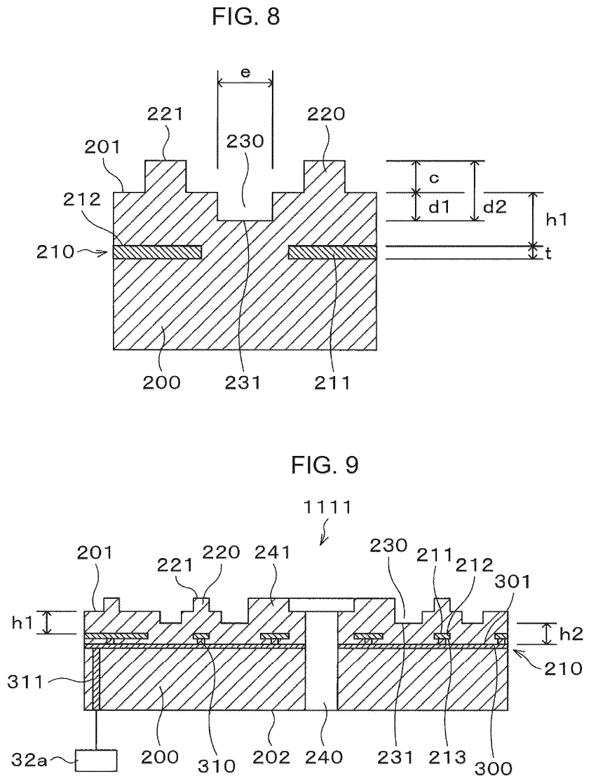

The clamping electrode layer 210 (clamping electrode layer segments 211), the protrusions 220, and the grooves 230 will now be described, focusing on their dimensions and positional relationship. As shown in FIG. 8, a depth d1 of the groove 230 (the dimension from the upper surface 201 of the dielectric member 200 to the bottom surface 231 of the groove 230) is greater than or equal to a height c of the protrusion 220 (the dimension from the upper surface 221 of the protrusion 220 to the upper surface 201 of the dielectric member 200). A depth d2 of the groove 230 (the dimension from the upper surface 221 of the protrusion 220 to the bottom surface 231 of the groove 230) is at least twice the height c of the protrusion 220. For example, the height c of the protrusion 220 is 5 to 20 μm, and the depth d2 of the groove 230 is 10 to 40 μm. A width e of the groove 230 is, but not limited to, 0.3 to 10 mm.

A distance h1 between the upper surface 201 of the dielectric member 200 and upper surfaces 212 of the clamping electrode layer segments 211 is, for example, 0.25 to 1 mm. Each clamping electrode layer segment 211 has a thickness t of, for example, 10 to 100 um. The distance between the bottom surfaces 231 of the grooves 230 and the upper surface 201 of the dielectric member 200 may be greater than, equal to, or less than the distance h1.

As described with reference to FIGS. 15A to 15C, the upper surface 201 of the dielectric member 200 and the bottom surfaces 231 of the grooves 230 wear down and their levels are lowered when plasma processing is performed on the substrate W. The upper surface 201 is degraded by exposure to plasma in the plasma processing, and is thus machined to form new multiple protrusions 220 (formation of new protrusions). The ESC 1111 is thus maintained and reused. When the clamping electrode layer segments 211 are located under the bottom surfaces 231 of the grooves 230 in the dielectric member 200, the distance between the bottom surfaces 231 and the clamping electrode layer segments 211 is shorter. More specifically, the portion of the dielectric member 200 between the bottom surfaces 231 and the clamping electrode layer segments 211 is thinner than the portion of the dielectric member 200 between the upper surface 201 and the upper surfaces 212 of the clamping electrode layer segments 211. This may decrease the dielectric strength of the grooves 230 and decrease the withstand voltage margin between the upper surface 201 of the dielectric member 200 and the back surface of the substrate W, possibly causing abnormal discharge between the upper surface 201 and the back surface of the substrate W.

In contrast, in the present embodiment, the multiple clamping electrode layer segments 211 are not located under the bottom surfaces 231 of the grooves 230. This can avoid decreasing the dielectric strength of the grooves 230 when the upper surface 201 of the dielectric member 200 and the bottom surfaces 231 of the grooves 230 wear down or new protrusions are formed. This prevents or reduces abnormal discharge between the upper surface 201 of the dielectric member 200 and the back surface of the substrate W.

The structure also allows new protrusions to be formed appropriately with no or reduced abnormal discharge. In other words, the structure can increase the yield of formation of new protrusions. The ESC 1111 can thus be maintained and appropriately reused. In other words, the structure according to the present embodiment allows maintenance and reuse of the ESC 1111 with no or reduced abnormal discharge between the ESC 1111 and the substrate W.

Although the structure of the substrate support surface of the dielectric member 200 has been described above, the present embodiment is also applicable to the structure of the ring support surface of the annular portion 111b in the dielectric member 200. More specifically, the portion under the ring support surface may also have the structure in which the multiple clamping electrode layer segments 211 of the clamping electrode layer 210 are not located under the bottom surfaces 231 of the grooves 230. This prevents or reduces abnormal discharge between the upper surface 201 of the dielectric member 200 and the back surface of the edge ring.

### Second Embodiment

A second embodiment describes an example structure and method for feeding power to the clamping electrode layer 210 in the ESC 1111 according to the first embodiment. FIG. 9 is a schematic sectional view of the ESC 1111 according to the second embodiment.

As shown in FIG. 9, a feeder electrode layer 300 is located in the dielectric member 200. The feeder electrode layer 300 is located across the entire dielectric member 200 in the planar direction. The feeder electrode layer 300 is at a lower position than the multiple clamping electrode layer segments 211 of the clamping electrode layer 210. A distance h2 between the bottom surfaces 231 of the grooves 230 and an upper surface 301 of the feeder electrode layer 300 is, for example, the same as the distance h1 between the upper surface 201 of the dielectric member 200 and the upper surfaces 212 of the clamping electrode layer segments 211. The feeder electrode layer 300 may be located in a part of the dielectric member 200 in the planar direction, rather than being located across the entire dielectric member 200 in the planar direction.

The feeder electrode layer 300 is electrically coupled to the clamping electrode layer 210 with conductive members 310. Multiple conductive members 310 are located for the respective clamping electrode layer segments 211 to couple lower surfaces 213 of the clamping electrode layer segments 211 and the upper surface 301 of the feeder electrode layer 300. The conductive members 310 are vias formed from, for example, a conductive ceramic material, a metal, or both these materials. The feeder electrode layer 300 is electrically coupled to the first DC generator 32a with a conductive member 311. The conductive member 311 is a via formed from, for example, a conductive ceramic material, a metal, or both these materials. The conductive member 311 is located on, for example, an outer peripheral portion of the feeder electrode layer 300. The feeder electrode layer 300 may be coupled to an AC power supply.

In this structure, the feeder electrode layer 300 feeds power from the first DC generator 32a to the multiple clamping electrode layer segments 211. More specifically, the same voltage is applied to all the clamping electrode layer segments 211 of the clamping electrode layer 210 through the conductive member 311, the feeder electrode layer 300, and the conductive members 310. This allows the ESC 1111 to appropriately apply a clamping force to clamp the substrate W.

### Third Embodiment

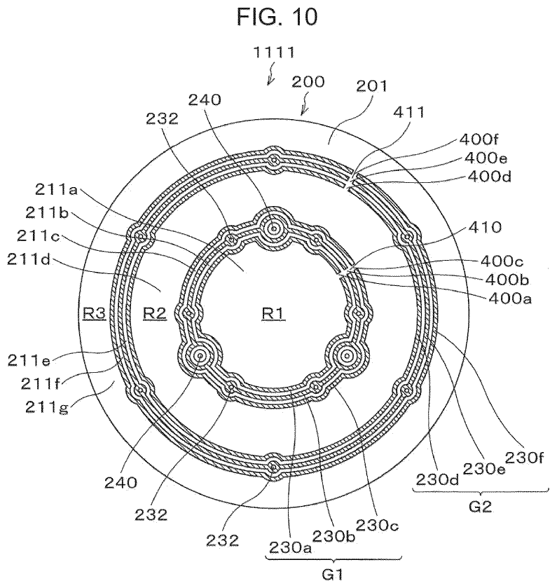

A third embodiment describes an example structure and method for feeding power to the clamping electrode layer 210 in the ESC 1111 according to the first embodiment. FIG. 10 is a schematic plan view of the ESC 1111 according to the third embodiment.

As shown in FIG. 10, each groove 230 includes at least one discontinuous portion 400. The three grooves 230a to 230c in the first groove set G1 respectively include discontinuous portions 400a to 400c. The discontinuous portions 400a to 400c are aligned on the same diameter. The three grooves 230d to 230f in the second groove set G2 respectively include discontinuous portions 400d to 400f. The discontinuous portions 400d to 400f are aligned on the same diameter. The discontinuous portions 400a to 400f are collectively referred to as the discontinuous portions 400.

A coupling electrode layer segment 410 is located under the discontinuous portions 400a to 400c. The coupling electrode layer segment 410 couples adjacent clamping electrode layer segments 211 across the corresponding groove 230, or specifically, electrically couples the clamping electrode layer segments 211a to 211d. A coupling electrode layer segment 411 is located under the discontinuous portions 400d to 400f. The coupling electrode layer segment 411 couples adjacent clamping electrode layer segments 211 across the corresponding groove 230, or specifically, electrically couples the clamping electrode layer segments 211d to 211g. At least one of the clamping electrode layer segments 211 is electrically coupled to the first DC generator 32a with a conductive member (e.g., a via), as in the second embodiment.

In this structure, the same voltage is applied to all the clamping electrode layer segments 211 of the clamping electrode layer 210 through the coupling electrode layer segments 410 and 411. This allows the ESC 1111 to appropriately apply a clamping force to clamp the substrate W. The numbers of coupling electrode layer segments 410 and 411 and their shapes are not limited to those in the present embodiment. For example, multiple coupling electrode layer segments 410 may be located for the groove set G1, and multiple coupling electrode layer segments 411 may be located for the groove set G2. The structure including multiple coupling electrode layer segments 410 and multiple coupling electrode layer segments 411 allows a higher yield of the ESC 1111.

### Fourth Embodiment

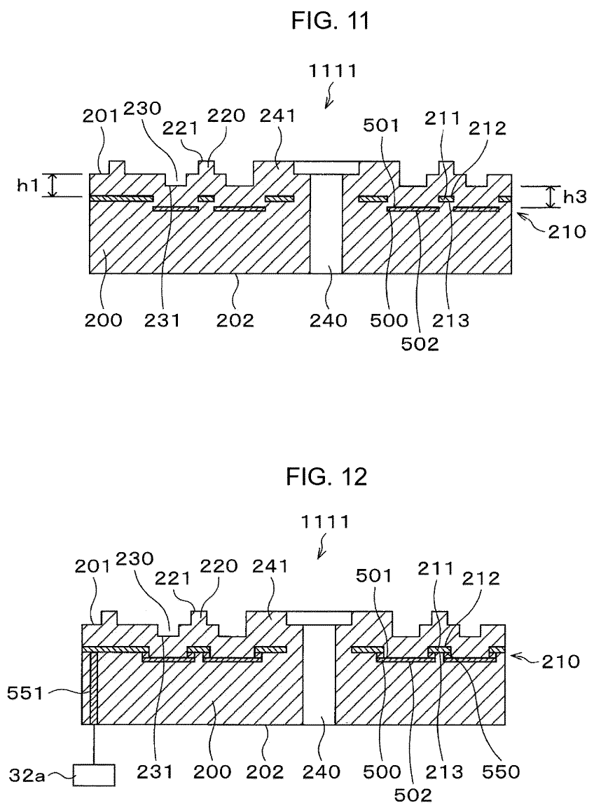

A fourth embodiment differs from the first embodiment in the structure of the ESC 1111. FIG. 11 is a schematic sectional view of the ESC 1111 according to the fourth embodiment.

As shown in FIG. 11, the multiple clamping electrode layer segments 211 are located under the portion of the upper surface 201 of the dielectric member 200 where the grooves 230 are not formed, and multiple clamping electrode layer segments 500 are located under the bottom surfaces 231 of the grooves 230. The clamping electrode layer segments 211 are similar to the clamping electrode layer segments 211 in the first embodiment, and will be hereafter referred to as first clamping electrode layer segments 211. The clamping electrode layer segments 500 are referred to as second clamping electrode layer segments 500. The second clamping electrode layer segments 500 are multiple clamping electrode layer segments into which a clamping electrode layer is divided in the radial direction, in the circumferential direction, or in both these directions, similarly to the first clamping electrode layer segments 211.

The second clamping electrode layer segments 500 are at a lower position than the first clamping electrode layer segments 211 in the dielectric member 200. A distance h3 between the bottom surfaces 231 of the grooves 230 and upper surfaces 501 of the second clamping electrode layer segments 500 is, for example, the same as the distance h1 between the upper surface 201 of the dielectric member 200 and the upper surfaces 212 of the clamping electrode layer segments 211. Each second clamping electrode layer segment 500 has a thickness that is the same as the thickness t of each first clamping electrode layer segment 211. For example, the thickness is 10 to 100 μm.

In the present embodiment, the second clamping electrode layer segments 500 are at a lower position than the first clamping electrode layer segments 211. In this structure, the portion of the dielectric member 200 between the second clamping electrode layer segments 500 and the bottom surfaces 231 of the grooves 230 is thicker than in a structure in which the second clamping electrode layer segments 500 are located at the same level as the first clamping electrode layer segments 211. This can avoid decreasing the dielectric strength of the grooves 230 when the upper surface 201 of the dielectric member 200 and the bottom surfaces 231 of the grooves 230 wear down or new protrusions are formed. This prevents or reduces abnormal discharge between the upper surface 201 of the dielectric member 200 and the back surface of the substrate W.

In the present embodiment, the distance h1 and the distance h3 can be adjusted to reduce a difference in clamping force on the substrate W between different positions in the planar direction. In other words, the substrate W can be clamped uniformly with a smaller difference between the clamping force on the substrate W applied by the first clamping electrode layer segments 211 and the clamping force on the substrate W applied by the second clamping electrode layer segments 500.

Although the structure of the substrate support surface of the dielectric member 200 has been described above, the present embodiment is also applicable to the structure of the ring support surface of the annular portion 111b in the dielectric member 200. More specifically, the portion under the ring support surface may also have the structure in which the clamping electrode layer 210 includes the multiple first clamping electrode layer segments 211 and the multiple second clamping electrode layer segments 500. This prevents or reduces abnormal discharge between the upper surface 201 of the dielectric member 200 and the back surface of the edge ring.

### Fifth Embodiment

A fifth embodiment describes an example structure and method for feeding power to the clamping electrode layer 210 in the ESC 1111 according to the fourth embodiment. FIG. 12 is a schematic sectional view of the ESC 1111 according to the fifth embodiment.

As shown in FIG. 12, in the dielectric member 200, the second clamping electrode layer segments 500 extend from the portion under the bottom surfaces 231 of the grooves 230 to the portion under the upper surface 201 of the dielectric member 200 where the grooves 230 are not formed. The first clamping electrode layer segments 211 and the second clamping electrode layer segments 500 are electrically coupled with conductive members 550. The conductive members 550 couple the lower surfaces 213 of the first clamping electrode layer segments 211 and the upper surfaces 501 of the second clamping electrode layer segments 500 under the portion of the upper surface 201 of the dielectric member 200 where the grooves 230 are not formed. The conductive members 550 are vias formed from, for example, a conductive ceramic material, a metal, or both these materials.

The first clamping electrode layer segments 211 are electrically coupled to the first DC generator 32a with a conductive member 551. The conductive member 551 is a via formed from, for example, a conductive ceramic material, a metal, or both these materials. The first clamping electrode layer segments 211 may be coupled to an AC power supply. The conductive member 551 may be electrically coupled to the second clamping electrode layer segments 500.

In this structure, the same voltage is applied to all the first clamping electrode layer segments 211 and the second clamping electrode layer segments 500 of the clamping electrode layer 210 through the conductive members 550 and 551. This allows the ESC 1111 to appropriately apply a clamping force to clamp the substrate W.

### Sixth Embodiment

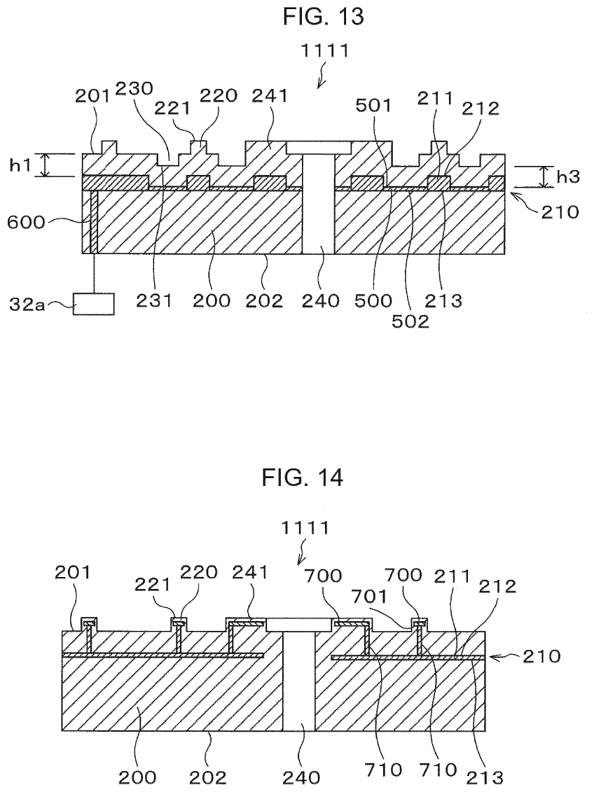

A sixth embodiment differs from the first embodiment or the fourth embodiment in the structure of the ESC 1111. FIG. 13 is a schematic sectional view of the ESC 1111 according to the sixth embodiment.

As shown in FIG. 13, the multiple first clamping electrode layer segments 211 are located under the portion of the upper surface 201 of the dielectric member 200 where the grooves 230 are not formed, and the multiple second clamping electrode layer segments 500 are located under the bottom surfaces 231 of the grooves 230.

The first clamping electrode layer segments 211 are similar to the clamping electrode layer segments 211 in the first embodiment and the fourth embodiment, but have a different thickness that is greater than the thickness t. The distance between the upper surface 201 of the dielectric member 200 and the upper surfaces 212 of the first clamping electrode layer segments 211 is the distance h1 described above. The lower surfaces 213 of the first clamping electrode layer segments 211 are located at the same level as lower surfaces 502 of the second clamping electrode layer segments 500.

The second clamping electrode layer segments 500 extend from the portion under the bottom surfaces 231 of the grooves 230 to the portion under the upper surface 201 of the dielectric member 200 where the grooves 230 are not formed, similarly to the clamping electrode layer segments 211 in the fourth embodiment. The second clamping electrode layer segments 500 are electrically coupled to the first clamping electrode layer segments 211 under the portion of the upper surface 201 of the dielectric member 200 where the grooves 230 are not formed. The distance between the bottom surfaces 231 of the grooves 230 and the upper surfaces 501 of the second clamping electrode layer segments 500 is the distance h3 described above. Each second clamping electrode layer segment 500 has the thickness t described above.

In the clamping electrode layer 210 in the dielectric member 200, the second clamping electrode layer segments 500 located under the bottom surfaces 231 of the grooves 230 are thinner than the first clamping electrode layer segments 211 located under the portion of the upper surface 201 of the dielectric member 200 where the grooves 230 are not formed. In this structure, the portion of the dielectric member 200 between the second clamping electrode layer segments 500 and the bottom surfaces 231 of the grooves 230 is thicker than in a structure in which the clamping electrode layer 210 has a uniform thickness across the entire clamping electrode layer 210 in the planar direction. This can avoid decreasing the dielectric strength of the grooves 230 when the upper surface 201 of the dielectric member 200 and the bottom surfaces 231 of the grooves 230 wear down or new protrusions are formed. This prevents or reduces abnormal discharge between the upper surface 201 of the dielectric member 200 and the back surface of the substrate W.

The first clamping electrode layer segments 211 are electrically coupled to the first DC generator 32a with a conductive member 600. The conductive member 600 is a via formed from, for example, a conductive ceramic material, a metal, or both these materials. The first clamping electrode layer segments 211 may be coupled to an AC power supply. The conductive member 600 may be electrically coupled to the second clamping electrode layer segments 500.

In this structure, the same voltage is applied to all the first clamping electrode layer segments 211 and the second clamping electrode layer segments 500 of the clamping electrode layer 210 through the conductive member 600. This allows the ESC 1111 to appropriately apply a clamping force to clamp the substrate W.

### Other Embodiments

In the first embodiment, the first clamping electrode layer segments 211 of the clamping electrode layer 210 are not located under the bottom surfaces 231 of the grooves 230. In the fourth embodiment and the sixth embodiment, the second clamping electrode layer segments 500 are located under the bottom surfaces 231 of the grooves 230 in an offset manner with respect to the first clamping electrode layer segments 211. More specifically, none of the clamping electrode layer segments is at a position under the bottom surfaces 231 of the grooves 230 and higher than the first clamping electrode layer segments 211 (at a position higher with respect to the distance h1). This structure can thus produce the effects of the above embodiments, or specifically, can prevent or reduce abnormal discharge.

Such a structure of the clamping electrode layer 210 is also applicable to any components other than the grooves 230 for supplying the heat transfer gas. The dielectric member 200 has, for example, grooves surrounding the lifter pin through-holes 240 and a groove receiving a temperature sensor, in addition to the grooves 230. Such grooves other than the grooves for supplying the heat transfer gas may also have the structure in which the first clamping electrode layer segments 211 are not located under the grooves or the second clamping electrode layer segments 500 are located under the grooves in an offset manner.

The structure of the clamping electrode layer 210 is also applicable to a thinner portion of the dielectric member 200 other than the portion having the grooves 230. More specifically, the dielectric member 200 may have the structure in which the first clamping electrode layer segments 211 are not located under a thinner portion or the second clamping electrode layer segments 500 are located under a thinner portion in an offset manner. For example, the dielectric member 200 can warp under temperature differences that occur when the substrate W is repeatedly heated and cooled in the plasma processing. Thus, the clamping electrode layer 210 may be curved to accommodate expected warpage of the dielectric member 200, rather than being parallel to the upper surface 201 of the dielectric member 200. Such a dielectric member 200 includes a thinner portion and may have the structure in which the first clamping electrode layer segments 211 are not located in the thinner portion or the second clamping electrode layer segments 500 are located in the thinner portion in an offset manner.

As shown in FIG. 14, the structure may include clamping electrode layer segments 700 in the protrusions 220, in the seal bands 241, or in both these components, in addition to including the clamping electrode layer segments 211 of the clamping electrode layer 210. The clamping electrode layer segments 700 are electrically coupled to the clamping electrode layer segments 211 with conductive members 710. The conductive members 710 couple lower surfaces 701 of the clamping electrode layer segments 700 and the upper surfaces 212 of the clamping electrode layer segments 211.

In the above embodiments, the grooves 230 produce a pressure difference in the radial direction in the space between the back surface of the substrate W and the upper surface 201 of the dielectric member 200 to control the temperature distribution in the surface of the substrate W. Such a pressure difference in the radial direction may be produced by dividing the upper surface 201 of the dielectric member 200 with seal bands located on the upper surface 201. FIG. 14 shows such an example. In other words, the structure of the clamping electrode layer 210 in one or more embodiments of the disclosure is applicable to the dielectric member 200 including no grooves 230, and is also applicable to the thinner portion of the dielectric member 200 other than the portion having the grooves 230 as described above.

Although the structure of the clamping electrode layer 210 in the dielectric member 200 has been described in the above embodiments, the structure according to the embodiments may be used for an electrode layer other than the clamping electrode layer 210. For example, the dielectric member 200 may include a bias electrode layer for drawing ion components in plasma to the substrate W. In this case, the bias electrode layer may be located similarly to the clamping electrode layer 210 in the above embodiments. More specifically, the dielectric member 200 may have the structure in which the bias electrode layer is not located under the bottom surfaces 231 of the grooves 230 or the bias electrode layer is located under the bottom surfaces 231 in an offset manner. The bias electrode layer having the structure according to the above embodiments can prevent or reduce abnormal discharge, although the bias electrode layer may potentially cause abnormal discharge in response to a high voltage applied. In other words, the structure according to the above embodiments is applicable to any electrode layer that is located in the dielectric member 200 and receives a high voltage.

The embodiments described herein are illustrative in all aspects and should not be construed to be restrictive. The components in the above embodiments may be eliminated, substituted, or modified in various forms without departing from the spirit and scope of the appended claims. For example, the components in the above embodiments may be combined as appropriate. These combinations produce the same advantageous effects as the respective embodiments in the combinations, as well as other advantageous effects that are apparent to those skilled in the art from the embodiments described herein.

The effects described herein are merely illustrative or exemplary and are not limitative. In other words, the technique according to one or more embodiments of the disclosure may produce other effects that will be apparent to those skilled in the art from the embodiments described herein, in addition to or in place of the above effects.

The example structures described below may also fall within the technical scope of the disclosure.
(1) An electrostatic chuck for supporting a substrate, the electrostatic chuck comprising:
a dielectric member having a substrate support surface;
a groove formed on an upper surface of the dielectric member; and
a plurality of electrode layer segments to which a high voltage is applied, the plurality of electrode layer segments being located in the dielectric member,
wherein at least one electrode layer segment of the plurality of electrode layer segments is located under a portion of the upper surface of the dielectric member where the groove is not formed, and
none of the plurality of electrode layer segments is located at a position under the groove and higher than the at least one electrode layer segment.
(2) The electrostatic chuck according to (1), wherein
none of the plurality of electrode layer segments is located under the groove.
(3) The electrostatic chuck according to (2), further comprising:
a feeder electrode layer being configured to feed power to the plurality of electrode layer segments, the feeder electrode layer being located at a lower position than the plurality of electrode layer segments in the dielectric member; and
conductive members coupling lower surfaces of the plurality of electrode layer segments and an upper surface of the feeder electrode layer.
(4) The electrostatic chuck according to (2), wherein
the groove is substantially looped in a plan view,
the groove includes at least one discontinuous portion,
the electrostatic chuck further comprises a coupling electrode layer segment located under the at least one discontinuous portion, and
the coupling electrode layer segment couples electrode layer segments of the plurality of electrode layer segments adjacent to each other across the groove.
(5) The electrostatic chuck according to (1), wherein
the plurality of electrode layer segments include a plurality of first electrode layer segments located under the portion of the upper surface of the dielectric member where the groove is not formed,
the plurality of electrode layer segments include a plurality of second electrode layer segments located under the groove, and
the plurality of second electrode layer segments are located at a lower position than the plurality of first electrode layer segments.
(6) The electrostatic chuck according to (5), further comprising:
conductive members located under the portion of the upper surface of the dielectric member where the groove is not formed, wherein the conductive members couples lower surfaces of the plurality of first electrode layer segments and upper surfaces of the plurality of second electrode layer segments.
(7) The electrostatic chuck according to (6), wherein
the plurality of second electrode layer segments are located under the portion of the upper surface of the dielectric member where the groove is not formed.
(8) The electrostatic chuck according to (5), wherein
the plurality of second electrode layer segments are thinner than the plurality of first electrode layer segments, and
the plurality of second electrode layer segments have upper surfaces at a lower position than upper surfaces of the plurality of first electrode layer segments.
(9) The electrostatic chuck according to any one of (1) to (8), wherein
the plurality of electrode layer segments are clamping electrode layer segments to clamp a substrate.
(10) The electrostatic chuck according to any one of (1) to (9), wherein
the groove is a groove configured to supply a heat transfer gas.
(11) A plasma processing apparatus for performing plasma processing on a substrate, the apparatus comprising:
a plasma processing chamber;
a base placed in the plasma processing chamber; and
an electrostatic chuck placed on an upper surface of the base to support a substrate, wherein the electrostatic chuck including
   a dielectric member having a substrate support surface,
   a groove formed on an upper surface of the dielectric member, and
   a plurality of electrode layer segments to which a high voltage is applied, the plurality of electrode layer segments being located in the dielectric member,
wherein at least one electrode layer segment of the plurality of electrode layer segments is located under a portion of the upper surface of the dielectric member where the groove is not formed, and
none of the plurality of electrode layer segments is located at a position under the groove and higher than the at least one electrode layer segment.

1. An electrostatic chuck for supporting a substrate, the electrostatic chuck comprising:
a dielectric member having a substrate support surface;
a groove formed on an upper surface of the dielectric member; and
a plurality of electrode layer segments to which a high voltage is applied, the plurality of electrode layer segments being located in the dielectric member,
wherein at least one electrode layer segment of the plurality of electrode layer segments is located under a portion of the upper surface of the dielectric member where the groove is not formed, and
none of the plurality of electrode layer segments is located at a position under the groove and higher than the at least one electrode layer segment.

2. The electrostatic chuck according to claim 1, wherein
none of the plurality of electrode layer segments is located under the groove.

3. The electrostatic chuck according to claim 2, further comprising:
a feeder electrode layer being configured to feed power to the plurality of electrode layer segments, the feeder electrode layer being located at a lower position than the plurality of electrode layer segments in the dielectric member; and
conductive members coupling lower surfaces of the plurality of electrode layer segments and an upper surface of the feeder electrode layer.

4. The electrostatic chuck according to claim 2, wherein
the groove is substantially looped in a plan view,
the groove includes at least one discontinuous portion,
the electrostatic chuck further comprises a coupling electrode layer segment located under the at least one discontinuous portion, and
the coupling electrode layer segment couples electrode layer segments of the plurality of electrode layer segments adjacent to each other across the groove.

5. The electrostatic chuck according to claim 1, wherein
the plurality of electrode layer segments include a plurality of first electrode layer segments located under the portion of the upper surface of the dielectric member where the groove is not formed,
the plurality of electrode layer segments include a plurality of second electrode layer segments located under the groove, and
the plurality of second electrode layer segments are located at a lower position than the plurality of first electrode layer segments.

6. The electrostatic chuck according to claim 5, further comprising:
conductive members located under the portion of the upper surface of the dielectric member where the groove is not formed, wherein the conductive members couples lower surfaces of the plurality of first electrode layer segments and upper surfaces of the plurality of second electrode layer segments.

7. The electrostatic chuck according to claim 6, wherein
the plurality of second electrode layer segments are located under the portion of the upper surface of the dielectric member where the groove is not formed.

8. The electrostatic chuck according to claim 5, wherein
the plurality of second electrode layer segments are thinner than the plurality of first electrode layer segments, and
the plurality of second electrode layer segments have upper surfaces located at a lower position than upper surfaces of the plurality of first electrode layer segments.

9. The electrostatic chuck according to claim 1, wherein
the plurality of electrode layer segments are clamping electrode layer segments to clamp a substrate.

10. The electrostatic chuck according to claim 1, wherein
the groove is a groove configured to supply a heat transfer gas.

11. A plasma processing apparatus for performing plasma processing on a substrate, the apparatus comprising:
a plasma processing chamber;
a base placed in the plasma processing chamber; and
an electrostatic chuck placed on an upper surface of the base to support a substrate, wherein the electrostatic chuck including:
a dielectric member having a substrate support surface,
a groove formed on an upper surface of the dielectric member, and
a plurality of electrode layer segments to which a high voltage is applied, the plurality of electrode layer segments being located in the dielectric member,
wherein at least one electrode layer segment of the plurality of electrode layer segments is located under a portion of the upper surface of the dielectric member where the groove is not formed, and
none of the plurality of electrode layer segments is located at a position under the groove and higher than the at least one electrode layer segment.
